(19) United States
(12) Patent Application Publication
(10) Pub. No.: US 2026/0005151 A1
(43) Pub. Date: Jan. 1, 2026

(54) ELECTRONIC DEVICE

(71) Applicant: InnoLux Corporation, Miao-Li County (TW)

(72) Inventors: Chia-Ping TSENG, Miao-Li County (TW); Po-Yun HSU, Miao-Li County (TW)

(73) Assignee: InnoLux Corporation, Miao-Li County (TW)

(21) Appl. No.: 19/218,641

(22) Filed: May 27, 2025

Related U.S. Application Data
(60) Provisional application No. 63/666,251, filed on Jul. 1, 2024.

(30) Foreign Application Priority Data
Dec. 19, 2024 (CN) 202411874595.3

(51) Int. Cl. H01L 23/538; H01L 21/48; H01L 23/15

(52) U.S. Cl. CPC H01L 23/5384; H01L 21/486; H01L 23/15

(57) ABSTRACT

An electronic device and a manufacturing method thereof are provided. The electronic device includes a substrate, a seed layer, and a conductor layer. The substrate has a first surface and a second surface opposite to the first surface. The substrate includes a through hole, and the through hole has a sidewall connected to the first surface and the second surface. The seed layer is disposed on the first surface, the second surface, and the sidewall. The conductor layer is disposed on the seed layer, and a roughness of a surface of the seed layer is greater than or equal to 1 nm and less than or equal to 1 μm.

### CROSS REFERENCE TO RELATED APPLICATION

This application claims the benefit of U.S. Provisional Application No. 63/666,251, filed on Jul. 1, 2024. The content of the application is incorporated herein by reference.

### BACKGROUND OF THE DISCLOSURE

### 1. Field of the Disclosure

The present disclosure relates to an electronic device and particularly to an electronic device for increasing adhesion between a substrate and a layer formed on the substrate.

### 2. Description of the Prior Art

Recently, packaging technology for electronic devices has been developed gradually towards 2.5D or 3D packaging method. In order to package a stack of dies, it has been developed to form through holes in an interposer or substrate, and a conductor layer is formed in the through holes to achieve vertical electrical connections. However, as line widths and line pitches of chips become smaller, aspect ratio of the through holes in the interposer or substrate is increased, which raises difficulty to form the conductor layer in the through holes.

### SUMMARY OF THE DISCLOSURE

It is an objective of the present disclosure to provide an electronic device and a manufacturing method thereof to increase adhesion between a conductor layer and other layers or between the conductor layer and the substrate, so as to form the conductor layer in a through hole.

According to an embodiment of the present disclosure, an electronic device is provided and includes a substrate, a first seed layer, and a conductor layer. The substrate has a first surface and a second surface opposite to the first surface, wherein the substrate includes a through hole, and the through hole has a sidewall connected to the first surface and the second surface. The first seed layer is disposed on the first surface, the second surface and the sidewall. The conductor layer is disposed on the first seed layer, wherein a roughness of a surface of the first seed layer is greater than or equal to 1 nm and less than or equal to 1 μm.

According to an embodiment of the present disclosure, a manufacturing method of an electronic device is provided and includes the following steps. First, a substrate is provided, wherein the substrate includes a first surface and a second surface opposite to the first surface. Then, at least one through hole penetrating through the substrate is formed, wherein the through hole has a sidewall connected to the first surface and the second surface. After that, a first seed layer is formed on the first surface, the second surface and the sidewall, and then, an electrochemical reaction is performed to form a second seed layer on the first seed layer. Next, a conductor layer is formed on the first seed layer and the second seed layer after the electrochemical reaction, wherein after the electrochemical reaction, a roughness of a surface of the first seed layer is greater than or equal to 1 nm and less than or equal to 1 μm.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 to FIG. 4 schematically illustrate cross-sectional views of structures at different steps of a manufacturing method of an electronic device according to a first embodiment of the present disclosure.

FIG. 5 schematically illustrates an enlarged part of an electronic device according to a second embodiment of the present disclosure.

FIG. 6 schematically illustrates a cross-sectional view of an electronic device according to a third embodiment of the present disclosure.

FIG. 7 schematically illustrates a cross-sectional view of an electronic device according to a fourth embodiment of the present disclosure.

FIG. 8 schematically illustrates a cross-sectional view of an electronic device according to a fifth embodiment of the present disclosure.

FIG. 9 schematically illustrates a cross-sectional view of an electronic device according to a sixth embodiment of the present disclosure.

FIG. 10 schematically illustrates a cross-sectional view of an electronic device according to a seventh embodiment of the present disclosure.

FIG. 11 schematically illustrates a cross-sectional view of an electronic device according to an eighth embodiment of the present disclosure.

FIG. 12 schematically illustrates a cross-sectional view of an electronic device according to a ninth embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and elements therein may not be drawn to scale. The numbers and sizes of the elements in the drawings are just illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. It does not mean that the element has any previous ordinal numbers, nor does it represent the order of a certain element and another element, or the sequence in a manufacturing method. These ordinal numbers are just used to make a claimed element with a certain name be clearly distinguishable from another claimed element with the same name.

In addition, when one element or layer is “connected to” the another element or layer, it may be understood that the element or layer is directly connected to the another element or layer, and alternatively, another element or layer may be between the element or layer and the another element or layer (indirectly). On the contrary, when the element or layer is “directly connected to” the another element or layer, it may be understood that the element or layer is physically or electrically connected to the another element or layer by no intervening element or layer between them. The term “connected to” may include means of “directly contact” or “indirectly contact”. Besides, the term “electrically connected to” or “coupled to” includes any direct or indirect means of electrical connection.

In the following contents, when one element is called “disposed on” another element, it does not limit the manufacturing method or sequence of the element or the another element.

As disclosed herein, the terms “approximately”, “essentially”, “about”, or “substantially” generally mean within 20%, 10%, 5%, 3%, 2%, 1%, or 0.5% of the reported numerical value or range. Numbers given herein is an approximated number, that is, without specifically describing with the terms “approximately”, “essentially”, “about”, or “substantially”, it may imply the meaning of the terms “approximately”, “essentially”, “about”, or “substantially”.

The term “between number A and number B” may be interpreted as situation of including number A and number B or including at least one of number A and number B, and may be interpreted as other numbers between number A and number B.

In the present disclosure, the depth, thickness, length, width, crystallinity, and aperture may be measured by using an X-ray diffractometer (XRD), an optical microscope (OM), a scanning electron microscope (SEM) or other approaches, but not limited thereto.

In the present disclosure, the definition of roughness may be observing an uneven surface to obtain a distance of 0.15 micrometers (μm) to 1 μm between a peak and a valley of the surface using SEM. The measurement of roughness may include using SEM, transmission electron microscope (TEM), etc. to observe peaks and valleys of the surface in the same proper magnified ratio, and the range of roughness is obtained by taking a sample with a unit length (e.g., 10 μm) and then comparing the peaks and the valleys. Here, the term “proper magnified ratio” means that in a visual field of this magnified ratio, at least 10 peaks may be observed on at least one surface to measure roughness (Rz) or averaged roughness (Ra).

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may, for example, be a semiconductor device and may be applied to any kind of devices. The electronic device may, for example, include a display device, a light-emitting device, a sensing device, an antenna device, a touch device, a tiled device, a package device or other suitable electronic devices, but not limited thereto. The electronic device may, for example, be a bendable, stretchable, foldable, rollable, and/or flexible electronic device, but not limited thereto. The display device may, for example, be applied to laptop, public display, tiled display, display for vehicle, touch display, television, monitor, smartphone, tablet, light source module, illumination apparatus, military equipment, or any electronic device applicable to the aforementioned product, but not limited thereto. The sensing device may, for example, be a sensing device used for detecting variation in capacitances, light, heat, or ultrasound, but not limited thereto. The sensing device may, for example, include a biosensor, a touch sensor, a fingerprint sensor, other suitable sensors, or any combination of sensors mentioned above. The display device may include liquid crystal molecules, light emitting diodes, a fluorescent material, a phosphor material, other suitable display medium, or any combination of elements mentioned above, but not limited thereto. The light emitting diode may, for example, include an organic light emitting diode (OLED), a mini light emitting diode (mini LED), a micro light emitting diode (micro LED), a quantum dot (QD), a quantum dot light emitting diode (e.g., QLED or QDLED), other suitable materials, or any combination of the aforementioned materials, but not limited thereto. The antenna device may, for example, include liquid crystal antenna, varactor diode antenna, or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems such as a driving system, a control system, a light source system, a shelf system, etc. The electronic device may include electronic units, in which the electronic units may include a passive element and an active element, and for example include a capacitor, a resistor, an inductor, a diode, a transistor, a sensor, etc. It is noted that the electronic device of the present disclosure may be any combination of the above-mentioned devices, but not limited thereto. The manufacturing method of the electronic device of the present disclosure may, for example, be applied to wafer-level package (WLP) process or panel-level package (PLP) process, wherein the WLP or the PLP may include chip-first process or chip-last process, but not limited thereto. The electronic device of the present disclosure may, for example, be applied to a power module, a semiconductor package device, a display device, a light-emitting device, a backlight device, an antenna device, a sensing device, or a tiled device, but not limited thereto. The electronic device may include system on a chip (SoC), system in a package (SiP), antenna in package (AiP), co-packaged optics (CPO), or any combination of the aforementioned devices, but not limited thereto.

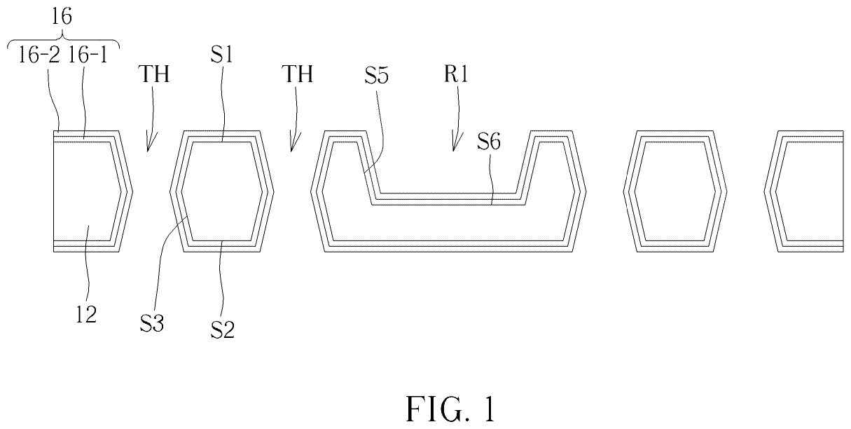

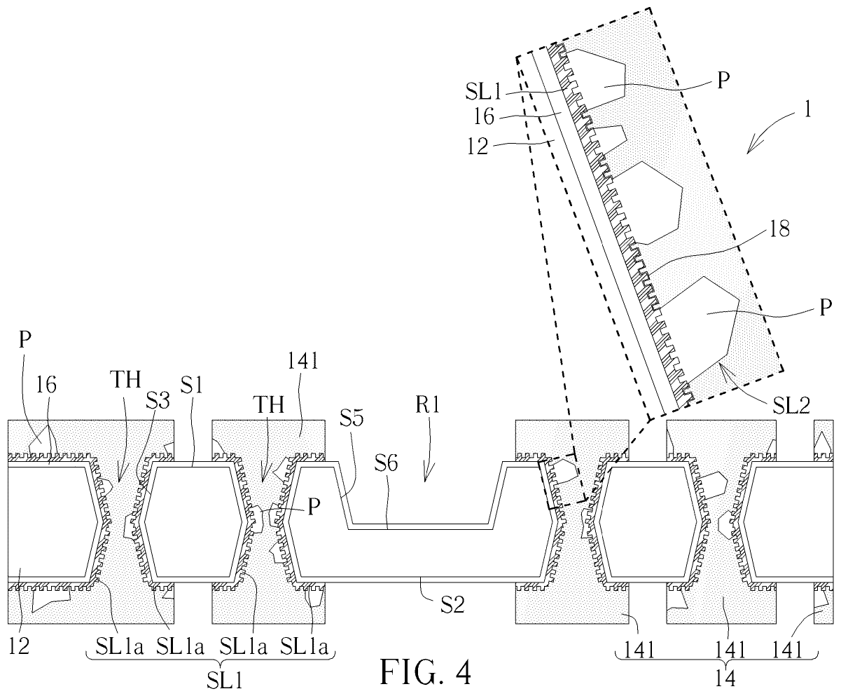

FIG. 1 to FIG. 4 schematically illustrate cross-sectional views of structures at different steps of a manufacturing method of an electronic device according to a first embodiment of the present disclosure, wherein FIG. 4 is a schematic cross-sectional view of the electronic device according to the first embodiment of the present disclosure. As shown in FIG. 1 to FIG. 4, the manufacturing method of the electronic device 1 may include at least the following steps: providing at least one substrate 12; forming a first seed layer SL1 on at least a portion of the first surface S1, the second surface S2 and the sidewall S3; performing an electrochemical reaction to form a second seed layer SL2 on the first seed layer SL1; and forming a conductor layer 14 on the first seed layer SL1 and the second seed layer SL2. After the electrochemical reaction, a roughness of a surface (e.g., a surface S4) of the first seed layer SL1 is greater than or equal to 1 nanometer (nm) and less than or equal to 1 micrometer (μm). The manufacturing method of the present disclosure is not limited to the above steps, and other steps may be performed before, after or during any of the steps mentioned above.

The manufacturing method of the electronic device 1 of this embodiment will be described in detail below with reference to FIG. 1 to FIG. 4. As shown in FIG. 1, the step of providing a substrate 12 may include performing a first patterning process on a first surface S1 of the substrate 12 and a second surface S2 opposite to the first surface S1 to form the substrate 12 including at least one through hole TH, wherein the through hole TH penetrates through the substrate 12, and the through hole TH may have a sidewall S3 connected to the first surface S1 and the second surface S2. In this embodiment, the number of the through hole TH is multiple, but not limited thereto.

In one embodiment, when the substrate 12 is a glass substrate, the first patterning process may include, for example, performing a modification process on positions of the substrate 12 where the through holes TH are to be formed and performing an etching process, a photolithography and etching process or other suitable processes on the modified substrate 12. The modification process may include, for example, laser irradiation. The etching process may include, for example, a wet etching process using an etching solution, so that different portions of the substrate 12 may have a significant etching selectivity ratio with respect to the etching solution to form the through holes TH. In other words, the substrate 12 may allow laser light to penetrate through, but not limited thereto. In some embodiments, the step of forming the through holes TH may be performed by etching the first surface S1 and the second surface S2 of the substrate 12 sequentially or simultaneously, but not limited thereto. The “modification” referred to in the present disclosure is to adjust chemical bonding strength of a local region of the substrate 12 or to weaken structural strength of the local region by laser or other suitable processes. According to some embodiments, the etching solution may include an acidic or alkaline liquid, wherein the acidic etching solution includes hydrofluoric acid, and the alkaline etching solution includes sodium hydroxide, but not limited thereto. In some embodiments, in a cross-sectional view, the through hole TH may be hourglass-shaped, rectangular, trapezoidal, inverted trapezoidal, or other suitable shapes. The patterning process referred to in the present disclosure may be performed from at least one viewing direction of the substrate 12, or simultaneously performed from two viewing directions of the substrate 12. For example, the through holes TH may be formed by performing the etching process on the first surface S1 or the second surface S2 of the substrate 12, or the through holes TH may be formed by performing the etching process on both the first surface S1 and the second surface S2 of the substrate 12, but the present disclosure is not limited thereto.

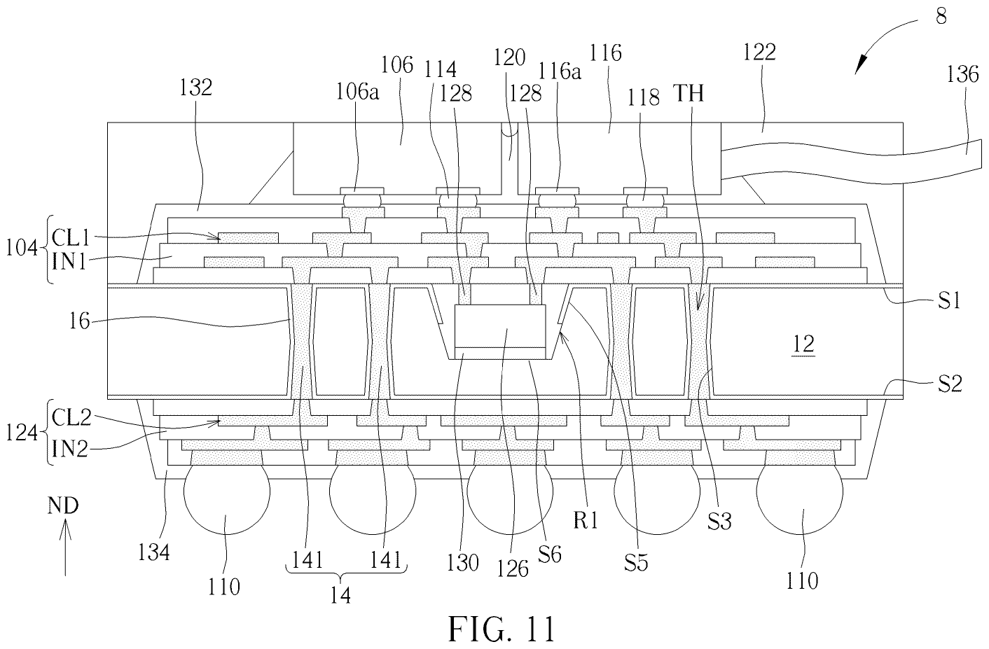

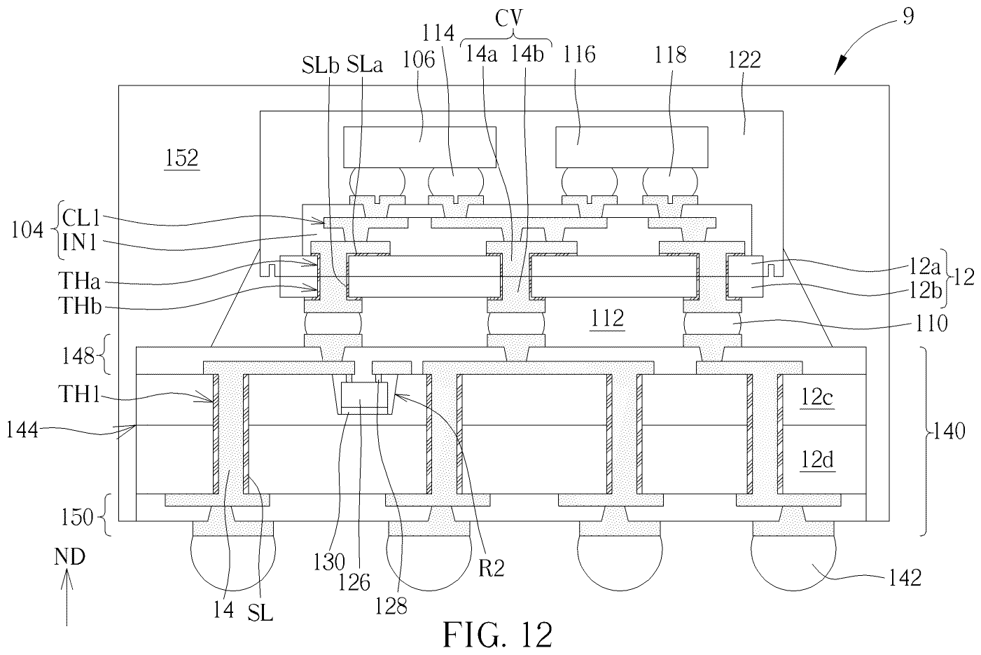

In the embodiment of FIG. 1, the step of providing the substrate 12 may further include forming at least one recess R1 on the first surface S1 (or the second surface S2) of the substrate 12 to accommodate at least one electronic element, such as the electronic element 126 shown in FIG. 11 or FIG. 12. The recess R1 may not penetrate through the substrate 12, but may be a blind hole of the substrate 12. According to some embodiments, the first surface S1, the second surface S2, the sidewalls S3 of the through holes TH, and/or the sidewall S5 and/or the bottom surface S6 of the recess R1 of the substrate 12 may have a roughness, and their average roughness may range from 0.1 μm to 1 μm to facilitate the enhancement of the adhesion between a layer formed subsequently and the substrate 12, but not limited thereto.

In the embodiment of FIG. 1, after the through holes TH are formed or the through holes TH and the recess R1 are formed, a buffer layer 16 may be optionally formed on the first surface S1, the second surface S2 and the sidewall S3 of the substrate 12, so that the buffer layer 16 may be disposed in at least a portion of each through hole TH. For example, the buffer layer 16 may cover the first surface S1, the second surface S2 and at least a portion of the sidewall S3 of each through hole TH. In some embodiments, the buffer layer 16 may be further disposed on at least a portion of the sidewall S5 of the recess R1 or cover the sidewall S5 and the bottom surface S6 of the recess R1. The method of forming the buffer layer 16 may include a deposition process or other suitable processes. The deposition process may, for example, include coating, evaporation, atomic layer deposition (ALD), or other physical deposition processes or chemical deposition processes. The buffer layer 16 may include an organic material or an inorganic material. For example, the buffer layer 16 may include polyimide (PI), poly-p-xylylene (also known as Parylene), benzocyclobutene (BCB), epoxy, polycarbonate (PC), polyethylene terephthalate (PET) or polyethylene naphthalate (PEN), other suitable thermosetting organic materials or a combination thereof, but not limited thereto. It should be noted that the buffer layer 16 may be provided on the first surface S1 or the second surface S2 of the substrate 12, or the buffer layer 16 may be provided on both the first surface S1 and the second surface S2 of the substrate 12, but not limited thereto.

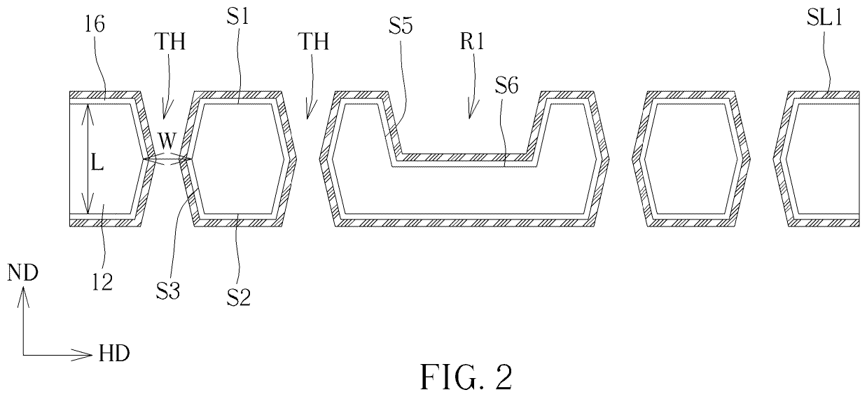

In some embodiments, a toughness of the buffer layer 16 may be greater than or equal to 0.1 kilojoules per square meter (kJ/m²) and less than or equal to 100 kJ/m² (i.e., 0.1 kJ/m²≤the toughness of the buffer layer 16≤100 kJ/m²). In the present disclosure, the toughness of a layer may be obtained by integrating an area under a stress-strain curve, and the stress-strain curve may be obtained by performing a tensile test on the layer using a universal testing machine (UTM). In some embodiments, the buffer layer 16 may include a single-layered or multilayered structure. A thickness of the buffer layer 16 may be less than or equal to 10 μm or range from 0.01 μm to 10 μm. A ratio of the thickness of the buffer layer 16 to a width of the through hole TH may range from 0.02 to 0.2. The width of the through hole TH may refer to a width of the through hole TH in a horizontal direction HD perpendicular to the normal direction ND of the first surface S1. For example, the buffer layer 16 may include a first sub-layer 16-1 and a second sub-layer 16-2, wherein the first sub-layer 16-1 is disposed between the substrate 12 and the second sub-layer 16-2. A material of the first sub-layer 16-1 and a material of the second sub-layer 16-2 may be identical to or different from each other. The first sub-layer 16-1 may include an organic material, and the second sub-layer 16-2 may include an organic material or an inorganic material, wherein the thickness of the buffer layer 16 may be a sum of thicknesses of the first sub-layer 16-1 and the second sub-layer 16-2. The ratio of the thickness of the buffer layer 16 at a center of the through hole TH to the minimum width W of the through hole TH may range from 0.02 to 0.2, such that the risk of crack of the substrate 12 may be reduced. The center of the through hole TH referred to in the present disclosure is a position of the through hole TH where the width of the through hole TH is the smallest, that is, the position corresponding to the minimum width W. According to some embodiments, the buffer layer 16 may optionally not exist. In some embodiments, although FIG. 2 to FIG. 4 in the subsequent steps does not show the first sub-layer 16-1 and the second sub-layer 16-2 in the buffer layer 16, they may still optionally include the first sub-layer 16-1 and the second sub-layer 16-2 shown in FIG. 1. In addition, the first sub-layer 16-1 and the second sub-layer 16-2 of FIG. 1 may be applied to any one of electronic devices of the following other embodiments.

As shown in FIG. 2, after the through hole TH or the buffer layer 16 is formed, the first seed layer SL1 may be formed on at least a portion of the first surface S1, the second surface S2 and the sidewall S3, or on the buffer layer 16. A method of forming the first seed layer SL1 may include, for example, an atomic layer deposition process, a physical vapor deposition (PVD) process, a chemical vapor deposition (CVD) process, a sputtering process, a coating process, other suitable deposition processes, or a combination thereof. The first seed layer SL1 may include a first metal, which may include, for example, titanium (Ti), titanium nitride (TiN), rubidium (Ru), alloys or a combination thereof, or other metals capable of being formed as a layer by a process. It should be noted that since the first metal has a certain activity, after the first seed layer SL1 is formed, a surface of the first seed layer SL1 away from the substrate 12 is exposed to an air environment. Accordingly, an interface oxide layer is formed on the surface of the first seed layer SL1. In the embodiment of FIG. 2, after the first seed layer SL1 is formed, the surface of the first seed layer SL1 away from the substrate 12 may be, for example, substantially flat. In an embodiment, an aspect ratio of the through hole TH may be greater than or equal to 8, greater than or equal to 10, or greater than or equal to 15, and the first seed layer SL1 may be formed on the buffer layer 16. According to some embodiments, the first seed layer SL1 may be formed directly on the first surface S1, the second surface S2, the sidewalls S3 of the through holes TH, and the sidewall S5 and the bottom surface S6 of the recess R1 of the substrate 12, but not limited herein. The aspect ratio of the through hole TH referred to in the present disclosure is L/W, where L may be regarded as the thickness of the substrate 12, and W is the minimum width of the through hole TH. It is noted that the first seed layer SL1 may be provided from the first surface S1 or the second surface S2 of the substrate 12, or the first seed layer SL1 may be provided from both the first surface S1 and the second surface S2 of the substrate 12.

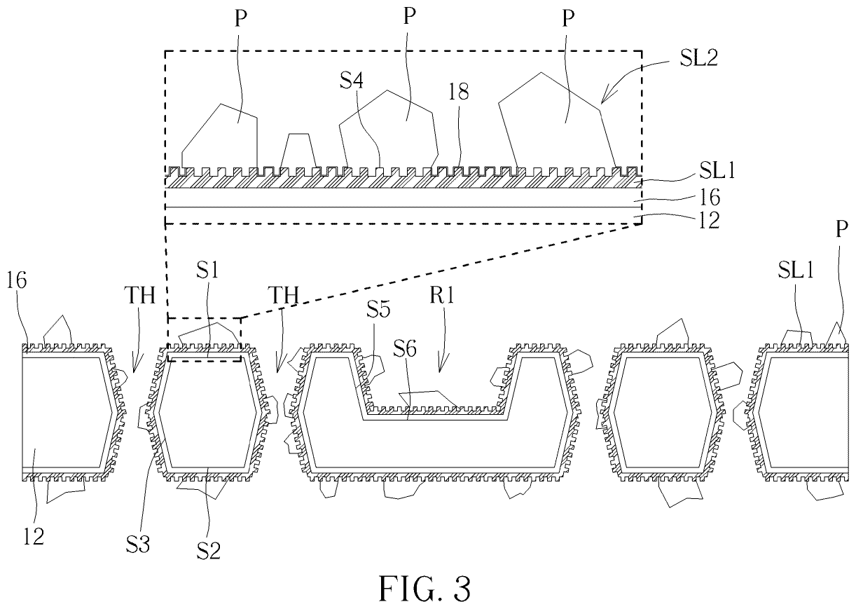

As shown in FIG. 3, after the first seed layer SL1 is formed, an electrochemical reaction is performed to form a second seed layer SL2 on the first seed layer SL1, wherein the second seed layer SL2 may include a second metal different from the first metal. Specifically, the electrochemical reaction may include immersing the first seed layer SL1 into a solution, wherein the solution includes a plurality of second metal ions, and the second metal ions may be reduced to the second metal, such that the second metal in metallic state may be formed on the first seed layer SL1. The second metal may, for example, include copper (Cu) or other suitable materials.

In the embodiment of FIG. 3, the electrochemical reaction may include oxidizing the first metal and reducing the second metal. Specifically, the electrochemical reaction may further include etching the surface of the first seed layer SL1 away from the substrate 12 with the solution to form an uneven surface S4. For example, the roughness of the surface S4 may range about 1 nm to about 1 μm. In other words, at least a part of the interface oxide layer 18 formed on the surface S4 of the first seed layer SL1 and a part of the first seed layer SL1 may be removed by the solution to expose the first metal, which may be referred to a following formula (1). Hence, the second metal ions in the solution may contact the exposed first metal. Since an oxidation potential of the first metal is greater than a reduction potential of the second metal, the second metal ions may generate an oxidation-reduction reaction with the first metal, as shown in a following formula (2):

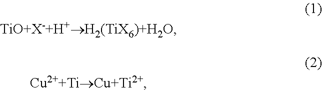

where X may include fluorine (F), chlorine (Cl) or other suitable elements. In this way, the second metal reduced to the metallic state may be deposited on the uneven surface S4 of the first seed layer SL1 to form the second seed layer SL2.

Furthermore, the pH value of the solution may range from 1 to 5, and the solution may include a plurality of X ions and a plurality of second metal ions, wherein the molar concentration of the X ions may, for example, range from 0.1 M to 1 M, and the molar concentration of the second metal ions may, for example, range from 0.5 M to 5.5 M. The X ions may be used to remove a part of the interface oxide layer 18 or a part of the first seed layer SL1. In this case, the thickness of the first seed layer SL1 may be non-uniform.

In the embodiment of FIG. 3, the second seed layer SL2 may include a plurality of metal islands P separated from each other. The metal islands P may, for example, be granular or other suitable shapes. In this case, a particle size of the metal island P may be less than 5 μm. In some embodiments, a density of the metal islands P may be greater than about 0.12 per square micrometer. In some embodiments, at least a portion of the metal islands P may be connected to each other while the portion of the metal islands P may have at least one hole. Alternatively, the metal islands P may be connected to each other to form a continuous layer.

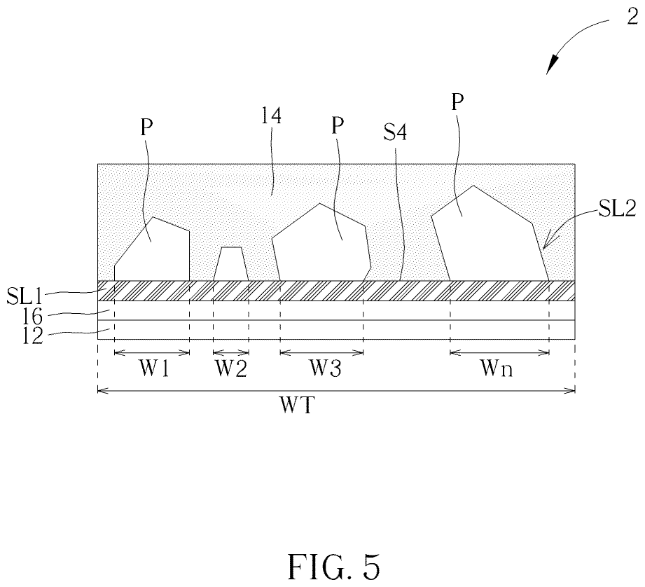

It should be noted that, since the surface S4 of the first seed layer SL1 is uneven, when the second seed layer SL2 is formed on the surface S4, the area of one of the metal islands P in contact with the surface S4 may be increased, thereby improving the adhesion between the metal island P and the first seed layer SL1. After the electrochemical reaction, when the second seed layer SL2 does not cover the entire surface of the first seed layer SL1, a part of the uneven surface S4 of the first seed layer SL1 without contacting the metal islands P may be exposed to be reacted with outside air, so that the interface oxide layer 18 may be formed on the part of the uneven surface S4. Since an activity of the second seed layer SL2 may be lower than that of the first seed layer SL1, an exposed surface of the second seed layer SL2 may not be reacted with the outside air, and no oxide layer is formed on the exposed surface of the second seed layer SL2 before forming the conductor layer 14. The electrochemical reaction may further include controlling a temperature of the solution to range from 25° C. to 80° C., such that the roughness of the surface S4 may be controlled to range from about 1 nm to about 1 μm. Accordingly, the risk of poor electrical property due to excessive roughness may be avoided. The electrochemical reaction may further include a concentration monitoring step of solution reactant. Since the X ions may be continuously consumed, the effective concentration of the reactant may be maintained by the concentration monitoring step. The “density” referred to in the present disclosure is obtained by, for example, taking a region of 10 μm×10 μm in a top view from a SEM with a ruler of 10 μm and calculating a projected area or an integrated area of all metal islands P in the region, wherein a ratio of the projected area or integrated area to 10 μm×10 μm is the density of the metal islands P. Alternatively, referring to FIG. 5, a cross-sectional view from a SEM with a ruler of 10 μm, for example, a width WT of the cross-sectional view being 10 μm, is taken, and a sum of bottom widths of all metal islands P in the region (i.e., width W1+width W2+width W3+ . . . width Wn) is calculated, wherein the ratio of the sum of the bottom widths to the width WT is regarded as the density of the metal islands P.

As shown in FIG. 4, after the electrochemical reaction, the conductor layer 14 is formed on the first seed layer SL1. In this embodiment, the conductor layer 14 may be formed in the through holes TH and on the first seed layer SL1 on the first surface S1 and the second surface S2. The method of forming the conductor layer 14 may include, for example, electroplating, chemical plating or other suitable processes. The conductor layer 14 may include, for example, the second metal or other suitable metal materials.

It is worthy to note that, since the interface oxide layer 18 may be formed on the first seed layer SL1, the interface oxide layer 18 may cause poor adhesion between the first seed layer SL1 and the layer formed in the subsequent steps, thereby affecting reliability of the electronic device. In this embodiment, since the second seed layer SL2 is formed between the formation of the first seed layer SL1 and the formation of the conductor layer 14, on one hand, a part of the interface oxide layer 18 may be reduced, and on the other hand, the second seed layer SL2 may be used as an auxiliary layer for the electroplating process, so that the adhesion between the conductor layer 14 and the first seed layer SL1 may be improved while the conductor layer 14 is formed on the first seed layer SL1. It should be noted that in the case that the conductor layer 14 is formed by the electroplating process, since the speed of the electroplating process for forming the second metal may be faster than the step of forming the second seed layer SL2, the production time of forming the conductor layer 14 may be shortened by the electroplating process. However, the method of forming the conductor layer 14 of the present disclosure is not limited to the electroplating process.

In one embodiment, the thickness of the second seed layer SL2 is less than the thickness of the conductor layer 14. A crystallinity of the second seed layer SL2 may be different from a crystallinity of the conductor layer 14, and for example, the crystallinity of the conductor layer 14 may be greater than the crystallinity of the second seed layer SL2. For example, when the conductor layer 14 includes the second metal, the crystallinity of the second metal in the conductor layer 14 may be greater than the crystallinity of the second metal in the second seed layer SL2. Moreover, the oxygen content of the second seed layer SL2 may be different from the oxygen content of the conductor layer 14, and for example, the oxygen content of the second seed layer SL2 is greater than the oxygen content of the conductor layer 14. For example, with the above configuration, the production time may be shortened, and the impedance of the redistribution structure may be reduced to improve the electrical property of the electronic device 1 formed subsequently, but not limited thereto.

After the conductor layer 14 is formed, a second patterning process is performed to remove a part of the conductor layer 14, a part of the second seed layer SL2 and a part of the first seed layer SL1 on the first surface S1 and the second surface S2, thereby forming the electronic device 1 of this embodiment. In the second patterning process, the first seed layer SL1 may be patterned into a plurality of discontinuous blocks SL1a, and each block SL1a may extend from the first surface S1 of the substrate 12 to the second surface S2 through the sidewall S3 of the corresponding through hole TH. Moreover, the conductor layer 14 may be patterned into a plurality of conductive blocks 141, and at least one of the conductive blocks 141 may extend from the first surface S1 of the substrate 12 to the second surface S2 through the corresponding through hole TH, so as to be used as a conductive via of the electronic device 1. In the embodiment of FIG. 4, the conductive blocks 141 may not be located in the recess R1, but not limited thereto. The second patterning process may, for example, include photolithography and etching processes or other suitable processes.

As mentioned above, since the interface oxide layer may be removed by the solution after the first seed layer SL1 is formed, the second metal ions may generate the oxidation-reduction reaction with the first seed layer SL1 to form the second seed layer SL2 on the uneven surface S4 of the first seed layer SL1, thereby improving the adhesion between the second seed layer SL2 and the first seed layer SL1. In addition, the formed second seed layer SL2 may help to form the conductor layer 14 on the first seed layer SL1 and the second seed layer SL2, such that the conductor layer 14 with a certain adhesion may be formed in the through holes TH with high aspect ratio.

As shown in FIG. 4, the electronic device 1 takes a single substrate 12 as an example, but not limited thereto. According to some embodiments, the substrate 12 of FIG. 4 may include a stack of multiple substrates 12, for example as shown in FIG. 12. In this case, the step of providing the substrate 12 may include providing a stack of multiple substrates 12, and the substrates 12 may be bonded to each other, so that through holes TH of different substrates 12 may overlap with each other to form one of the through hole that penetrates through all substrates 12. That is, the substrates 12 with the through holes TH may be formed separately first. Then, the substrates 12 may be disposed on a carrier, and a lamination process may be performed to bond different substrates 12 to each other through at least one intermediate layer disposed between the substrates 12, thereby forming the stack of substrates 12. After that, the carrier is removed. It should be noted that by stacking the substrates 12, a difference between the maximum width and the minimum width of the through hole penetrating through a whole of the substrates 12 may be reduced while improving the rigidity of the whole of the substrates 12. The intermediate layer may, for example, include an inorganic material or an organic material. In some embodiments, the lamination process may optionally include performing a pressing process on the substrates 12, but not limited thereto. In some embodiments, the step of bonding different substrates 12 to each other may be performed after the first seed layer SL1, the second seed layer SL2, and the conductor layer 14 are formed in each of the through holes TH of the different substrates 12.

As shown in FIG. 4, in the formed electronic device 1, since the roughness of the surface of the first seed layer SL1 may be greater than or equal to 1 nm and less than or equal to 1 μm, the adhesion between the conductor layer 14 disposed on the first seed layer SL1 and the first seed layer SL1 may be increased, so that the conductor layer 14 may be formed in the through hole TH. In addition, the second seed layer SL2 disposed between the first seed layer SL1 and the conductor layer 14 may further enhance the adhesion between the conductor layer 14 and the first seed layer SL1. In some embodiments, the buffer layer 16 may be selectively disposed between the substrate 12 and the first seed layer SL1 to reduce the risk of cracking or breakage of the substrate 12. In some embodiments, the interface oxide layer 18 may be formed on the surface S4 of the first seed layer SL1 without contacting the metal islands P and may be located between the first seed layer SL1 and the conductor layer 14. In other words, along the normal direction ND of the substrate 12, the interface oxide layer 18 does not overlap with the metal islands P to improve the quality of adhesion between the metal islands P and the first seed layer SL1.

The electronic device and the manufacturing method thereof are not limited to the above embodiments, and may have different embodiments. To simplify the description, same elements use the same reference characters as the first embodiment in different embodiments of the present disclosure. In order to clearly describe different embodiments, differences between the embodiments will be described below, and the repeated parts will not be detailed redundantly.

Refer to FIG. 5, which schematically illustrates an enlarged part of an electronic device according to a second embodiment of the present disclosure. In order to clearly show the first seed layer SL1 of this embodiment, FIG. 5 shows a partially enlarged diagram of the electronic device 2, but not limited thereto. As shown in FIG. 5, the electronic device 2 of this embodiment differs from the electronic device 1 of FIG. 4 in that the first seed layer SL1 of this embodiment includes a third metal that is not capable of being formed as a layer through a process, and the third metal has a property of a catalyst. Specifically, the first seed layer SL1 may include a polymer material and the third metal. Since the third metal is not capable of being independently formed as a thin film on the substrate 12, the third metal may be mixed in the polymer material. The polymer material is used to enable the third metal to be formed on and attached to the substrate 12. The polymer material may include, for example, PI, a fluorine-containing material or other suitable materials. The polymer material may be referred to as an adhesion promoter.

In the manufacturing method of this embodiment, the method of forming the first seed layer SL1 may include, for example, forming the polymer material mixed with the third metal on the first surface S1, the second surface S2 and the sidewall S3 of the substrate 12, and performing a baking process on the polymer material, so as to form the first seed layer SL1. The method of forming the polymer material on the substrate 12 may include, for example, a coating process or other suitable processes. In the embodiment of FIG. 5, the third metal may include a noble metal, such as palladium, gold, silver, platinum or other suitable metal materials. In this case, the solution in which the first seed layer SL1 is immersed may include a reducing agent and a plurality of second metal ions. In other words, the solution may be, for example, a chemical plating solution. The method of forming the second seed layer SL2 may include, for example, a chemical plating process or other suitable processes. In addition, the electrochemical reaction may include using the third metal as a catalyst to reduce the second metal, that is, the second metal ions may produce a reduction reaction with the reducing agent through the catalysis of the third metal, thereby being deposited and formed on the surface S4 of the first seed layer SL1. In FIG. 5, the solution may not have etching capability, so that the first seed layer SL1 may have the flat surface S4, but is not limited thereto. Since other parts and other steps of the manufacturing method of the electronic device 2 in this embodiment may be identical or similar to those of the above embodiment, the above content is referred to for them, and they will not be repeated herein.

In some embodiments, the polymer material may, for example, include the same material as the buffer layer. In this case, the step of forming the buffer layer 16 and the step of forming the first seed layer SL1 may, for example, use the same hard baking process. Specifically, a soft baking process may be performed after the buffer layer 16 is formed on the substrate 12, and another soft baking process and a hard baking process may be performed in sequence after the first seed layer SL1 is formed on the buffer layer 16, thereby simultaneously solidifying the buffer layer 16 and the first seed layer SL1. In the buffer layer 16 and the first seed layer SL1 formed by the above method, the concentration of the third metal may decrease sequentially from the surface S4 toward a surface of the buffer layer 16 facing the substrate 12.

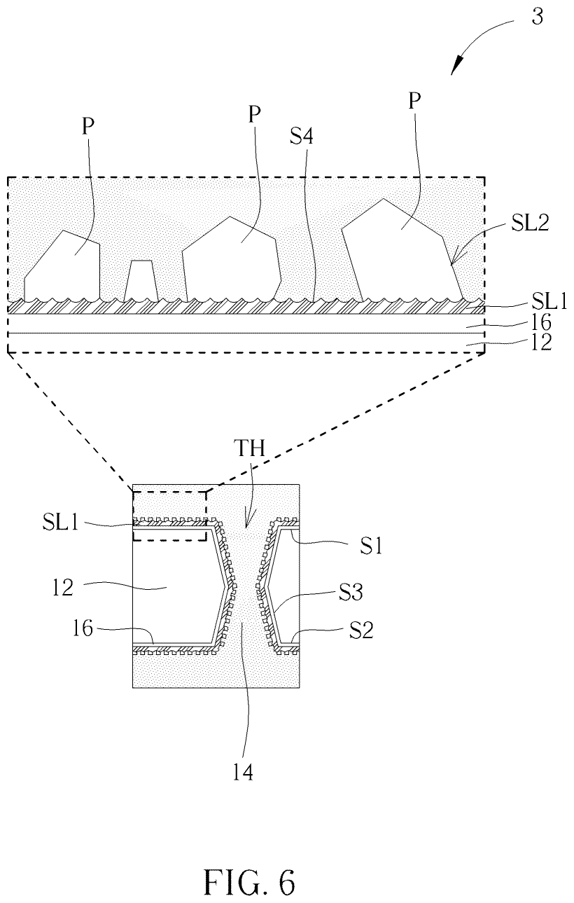

Refer to FIG. 6, which schematically illustrates a cross-sectional view of an electronic device according to a third embodiment of the present disclosure. As shown in FIG. 6, the electronic device 3 of this embodiment differs from the electronic device 1 shown in FIG. 4 in that the uneven surface S4 of the first seed layer SL1 of this embodiment may be wavy. For example, the uneven surface S4 may have a plurality of arc-shaped recesses, but not limited thereto.

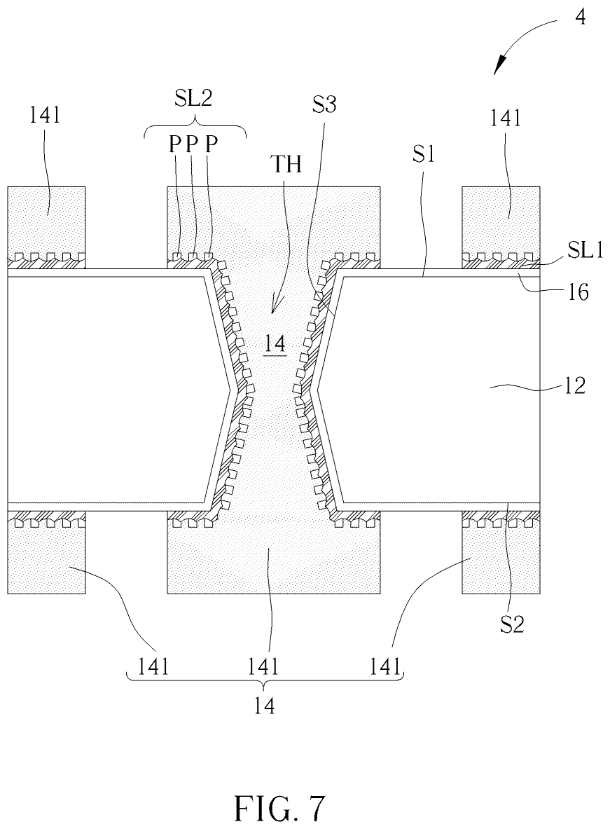

Refer to FIG. 7, which schematically illustrates a cross-sectional view of an electronic device according to a fourth embodiment of the present disclosure. As shown in FIG. 7, the electronic device 4 of this embodiment differs from the electronic device 3 shown in FIG. 6 in that a portion of the first seed layer SL1 on the first surface S1 and/or the second surface S2 in this embodiment may be discontinuous. In the embodiment of FIG. 7, the conductor layer 14 may alternatively include a plurality of conductive blocks 141 separated from each other.

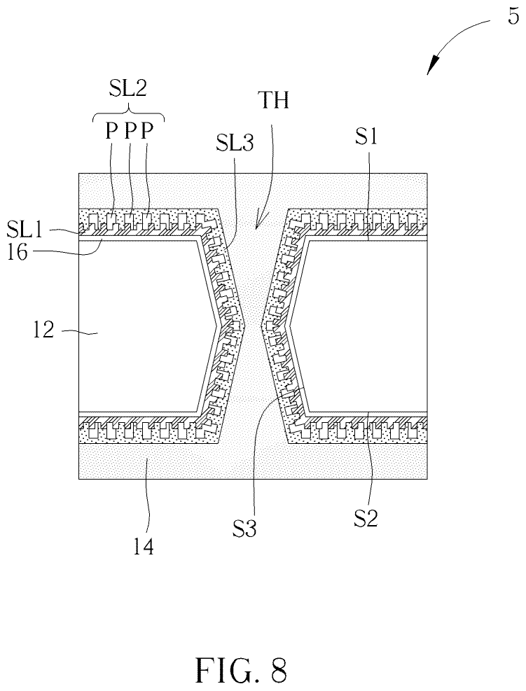

Refer to FIG. 8, which schematically illustrates a cross-sectional view of an electronic device according to a fifth embodiment of the present disclosure. As shown in FIG. 8, the electronic device 5 of this embodiment differs from the electronic device 1 shown in FIG. 4 in that the electronic device 5 of this embodiment may further include a third seed layer SL3, which is at least disposed among the metal islands P of the second seed layer SL and be connected to the metal islands P. In the embodiment of FIG. 8, the third seed layer SL3 may, for example, cover the second seed layer SL2 and the first seed layer SL1, but not limited thereto. According to some embodiments, a roughness of a surface of the third seed layer SL3 is greater than or equal to 1 nanometer and less than or equal to 1 micrometer.

In the manufacturing method of this embodiment, the third seed layer SL3 may be formed between the metal islands P between the step of forming the second seed layer SL2 and the step of forming the conductor layer 14. In the embodiment of FIG. 8, since the metal islands P are separated from each other, for example, in the case that the density of the metal islands P is low, the method of forming the third seed layer SL3 may include the chemical plating process to facilitate forming a continuous layer, but not limited thereto. In some embodiments, the method of forming the third seed layer SL3 may include other suitable processes, such as electroplating process or sputtering process. In some embodiments, when the metal islands P are connected to each other, such that the second seed layer SL2 has holes, the third seed layer SL3 may be disposed just in the holes, but not limited thereto. Other parts and other steps of the manufacturing method of the electronic device 5 in this embodiment may be identical or similar to the embodiment of FIG. 1 to FIG. 4, so that the above content is referred to for them, and they will not be detailed redundantly.

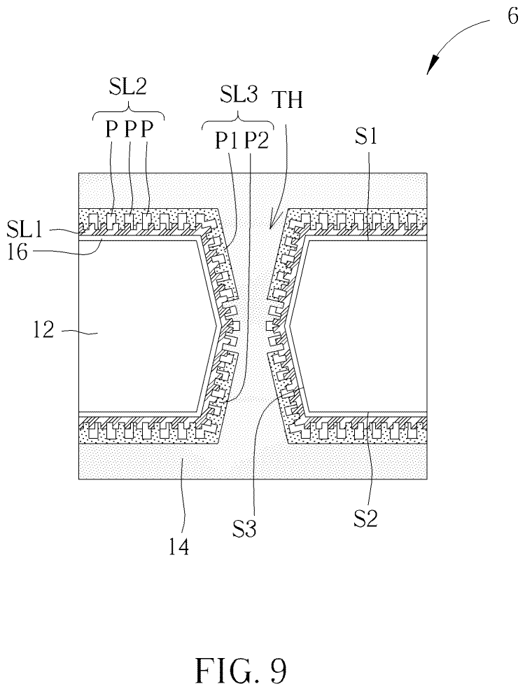

Refer to FIG. 9, which schematically illustrates a cross-sectional view of an electronic device according to a sixth embodiment of the present disclosure. As shown in FIG. 9, the electronic device 6 of this embodiment differs from the electronic device 5 shown in FIG. 8 in that the third seed layer SL3 may not cover the sidewall S3 of the through hole TH, but may be disposed on a portion of the sidewall S3. In other words, the third seed layer SL3 may include a first portion P1 and a second portion P2 separated from each other, wherein the first portion P1 is disposed on the first surface S1 and extends to a portion of the sidewall S3 of the through hole TH adjacent to the first surface S1, and the second portion P2 is disposed on the second surface S2 and extends to a portion of the sidewall S3 of the through hole TH adjacent to the second surface S2. In the embodiment of FIG. 9, the density of the metal islands P may be higher, and the method of forming the third seed layer SL3 may include a sputtering process, so that the third seed layer SL3 may fill the discontinuous region of the second seed layer SL2, but not limited thereto. Other parts and other steps of the manufacturing method of the electronic device 6 in this embodiment may be identical or similar to the embodiment of FIG. 1 to FIG. 4 or the embodiment of FIG. 8, so the above content is referred to for them, and they will not be detailed redundantly.

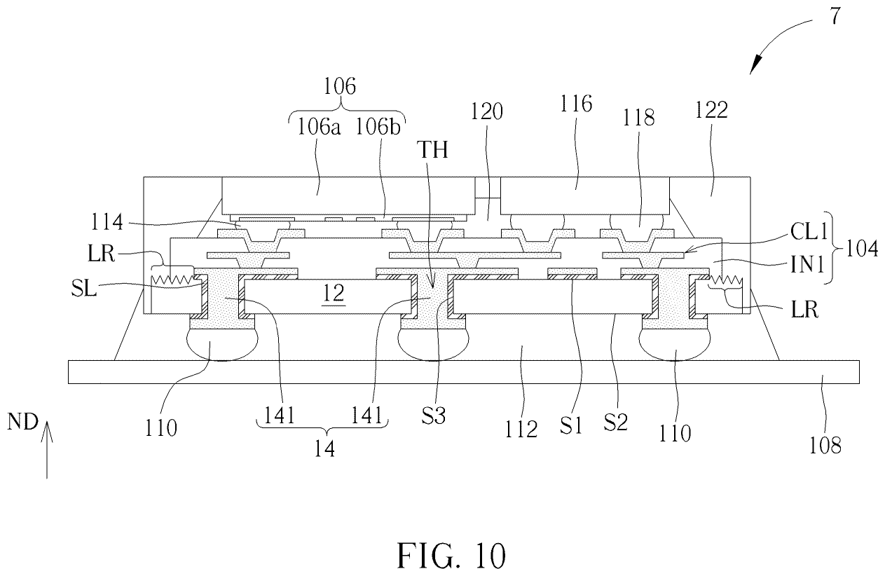

Refer to FIG. 10, which schematically illustrates a cross-sectional view of an electronic device according to a seventh embodiment of the present disclosure. As shown in FIG. 10, the electronic device 7 of this embodiment may include a substrate 12, a seed layer SL, a conductor layer 14, a redistribution structure 104, and at least one electronic unit 106. In this embodiment, the substrate 12, the seed layer SL and the conductor layer 14 may adopt any one of the above-mentioned electronic device 1 of FIG. 4 to the above-mentioned electronic device 6 of FIG. 9. For example, the substrate 12 may include at least one substrate 12 of any one of the electronic device 1 of FIG. 4 to the electronic device 6 of FIG. 9, the seed layer SL may include the first seed layer SL1 and the second seed layer SL2 shown in any one of FIG. 4 to FIG. 9, and the conductor layer 14 may include a plurality of conductive blocks 141, but not limited thereto. In some embodiments, the seed layer SL may further include the third seed layer SL3 as shown in FIG. 8 or FIG. 9, but not limited thereto.

The redistribution structure mentioned here or in the following content may be electrically connected to each chip or each electronic unit through bonding pads or other bonding elements. In addition, the redistribution structure may include at least one conductive layer and at least one insulating layer to redistribute traces and/or further increase fan-out areas of traces, or different electronic units may be electrically connected to each other through the redistribution structure. Alternatively, the redistribution structure may be a substrate used as a routing of an electrical interface between one circuit and another circuit. The purpose of the redistribution structure is to expand a connection to have wider spacing or to redistribute the connection to another connection with different spacing. As shown in FIG. 10, the redistribution structure 104 may be disposed on the substrate 12, and the electronic unit 106 may be disposed on the redistribution structure 104 and bonded to the redistribution structure 104 through bonding pads 114, so that the electronic unit 106 may be electrically connected to other elements through the redistribution structure 104 and the conductor layer 14. The bonding pad 114 may, for example, include a solder ball, nickel, gold, copper, gallium or other suitable conductive materials. The redistribution structure 104 may include at least one conductive layer CL1 and at least one insulating layer. In this embodiment, the redistribution layer 104 may include a plurality of insulating layers, and a combination of the insulating layers is represented as a single insulating layer IN1, but the present disclosure is not limited thereto. Each insulating layer may have at least one through hole, so that the conductive layer CL1 has an electrical connection in a stacking direction of the insulating layers. The conductive layer CL1 farthest from the substrate 12 may include a plurality of pads for being bonded to the electronic unit 106 or other suitable elements. The stacking direction referred to in the present disclosure may be regarded as the normal direction ND of the substrate 12.

For example, the insulating layer IN1 may include polyimide (PI), photosensitive polyimide (PSPI), build-up material (ABF), silicon oxide (SiOx), silicon nitride (SiNx) and silicon oxynitride (SiOxNy). The conductive layer CL1 may include a conductive material, for example, including copper (Cu), titanium (Ti), aluminum (Al), molybdenum (Mo), nickel (Ni), ruthenium (Ru), tantalum (Ta), tungsten (W), nitride, carbide or other conductive materials or any combination thereof, but not limited thereto.

In some embodiments, the electronic device 7 may optionally further include the buffer layer 16 of any one of FIG. 4 to FIG. 9, but not limited thereto. In some embodiments, the thickness of one of the insulating layers of the redistribution structure may be greater than the buffer layer. The thickness of one of the insulating layers may be, for example, about 5 mm to about 15 mm. It should be noted that the substrate 12 may be used as a core substrate, a supporting substrate or an interposer for the redistribution structure 104 of the electronic device 7 and may reduce warping during the step of forming the redistribution structure 104, thereby improving the production yield of the electronic device 7. For example, the substrate 12 may include a glass substrate, a silicon-containing transparent material, an optical layer, an acrylic plate, other transparent materials or a combination thereof and have a certain stiffness and insulation. In other words, the rigidity of the substrate 12 may be greater than the rigidity of the redistribution structure 104, and for example, the rigidity of the substrate 12 is greater than the rigidity of the insulating layer IN1 of the redistribution structure 104, so that the substrate 12 may mitigate the warping while being used to carry the redistribution structure 104, but not limited thereto. Alternatively, a dielectric loss of the substrate 12 is less than a dielectric loss of the insulating layer IN1 of the redistribution structure 104, so that the substrate 12 may improve the electrical property of the electronic device 7 while being used to carry the redistribution structure 104, but not limited thereto. According to some embodiments, the redistribution structure 104 may be formed on at least one side of the substrate 12. In some embodiments, a surface of the substrate 12 of the electronic device 7 may optionally have a local region LR being roughened, that is, a roughness of the local region LR may be greater than a roughness of other regions of the surface. The local region LR may include an outer peripheral region of the substrate 12 or a region that does not overlap with the electronic unit 106 and another electronic unit 116, so as to increase adhesion between the substrate 12 and other layers. Since the local region LR with greater roughness does not overlap with the electronic unit 106 and the electronic unit 116, the stress of the electronic unit 106 and the electronic unit 116 subjected by being disposed on the substrate 12 may be reduced to decrease the risk of damages of them, but not limited thereto.

In the embodiment of FIG. 10, the electronic unit 106 may include a chip 106a and a redistribution structure 106b, and the redistribution structure 106b is disposed on an active surface of the chip 106a. The redistribution structure 106b may be bonded to the redistribution structure 104 through the bonding pads 114 and electrically connected to the redistribution structure 104. In some embodiments, the electronic device 7 may optionally include another electronic unit 116 disposed on the redistribution structure 104. The electronic unit 116 may include a chip, for example, and the active surface of the chip may be electrically connected to the redistribution structure 104 through bonding pads 118. In some embodiments, the electronic unit 116 may be electrically connected to the electronic unit 106 through the redistribution structure 104 and/or electrically connected to a circuit board 108 through the redistribution structure 104. The functions of the electronic unit 106 and the electronic unit 116 may be adjusted as required. The electronic unit 106 and/or the electronic unit 116 may include a chip, a chip package structure, a chip assembly structure or other types of element structures. The electronic unit 106, the electronic unit 116 or the chip may have the active surface and a back surface, wherein a surface of the electronic unit 106, the electronic unit 116 or the chip with pads or input-output pads (I/O pads) may be, for example, the active surface referred to in the present disclosure for being bonded to the bonding pads, and another surface of the chip opposite to the active surface is the back surface.

In FIG. 10, the electronic device 7 may further optionally include another adhesive layer 120 disposed between the electronic unit 106 and the redistribution structure 104 and between the electronic unit 116 and the redistribution structure 104. The electronic device 7 may further optionally include a protection layer 122 at least surrounding the electronic unit 106. In some embodiments, the protection layer 122 may selectively further surround the redistribution structure 104 or further surround the redistribution structure 104 and the substrate 12. The protection layer 122 may include a packaging material, such as epoxy molding compound (EMC) or other suitable materials. In the present disclosure, one element “surrounding” another element may refer to that in a cross-sectional view of the electronic device, the element at least contacts a side surface of the another element.

In the embodiment of FIG. 10, the electronic device 7 may further selectively include a circuit board 108, and each conductive block 141 may be bonded to the circuit board 108 through a corresponding bonding pad 110, such that the electronic unit 106 may be electrically connected to the circuit board 108. In some embodiments, the electronic device 7 may further selectively include an adhesive layer 112 disposed between the substrate 12 and the circuit board 108 to enhance the adhesion between the substrate 12 and the circuit board 108. The adhesive layer 112 and the adhesive layer 120 may include, for example, an underfill material or other suitable materials.

In the manufacturing method of the electronic device 7 of FIG. 10, the substrate 12, the seed layer SL and the conductor layer 14 may be provided according to the method of the above-mentioned embodiment, and then the redistribution structure 104 may be formed on the substrate 12. The step of forming the redistribution structure 104 may include providing at least one insulating layer and at least one conductive layer CL1 stacked. For example, this step includes processes such as photolithography, etching, surface treatment, laser, electroplating, etc. The surface treatment may include roughening a surface of the insulating layer or a surface of the conductive layer to improve its adhesion.

After the redistribution structure 104 is formed, the electronic unit 106 and the electronic unit 116 may be bonded to the redistribution structure 104. Then, a molding process is performed to form the protection layer 122 at least surrounding the electronic unit 106. Afterwards, the conductive blocks 141 are bonded to the circuit board 108 to form the electronic device 7 of this embodiment.

Refer to FIG. 11, which schematically illustrates a cross-sectional view of an electronic device according to an eighth embodiment of the present disclosure. As shown in FIG. 11, the electronic device 8 of this embodiment differs from the electronic device 7 of FIG. 10 in that the electronic device 8 may further include another redistribution structure 124, which is disposed on a side of the substrate 12 away from the redistribution structure 104. The structure of the redistribution structure 124 may be similar to that of the redistribution structure 104, so that it may include at least one conductive layer CL2 and at least one insulating layer IN2. The above content may be referred to for the redistribution structure 124, and the redistribution structure 124 will not be repeated herein.

In the embodiment of FIG. 11, the buffer layer 16 may extend from the first surface S1 to the second surface S2 through the sidewall S3 of the through hole TH and may be a continuous layer. In some embodiments, the buffer layer 16 may not extend to the bottom surface S6 of the recess R1 of the substrate 12, but not limited thereto. In some embodiments, the buffer layer 16 may cover a portion of the surface of the substrate 12, but not limited thereto. In addition, the conductive blocks 141 of this embodiment may not extend to the first surface S1 and the second surface S2 of the substrate 12. In other words, in the stacking direction, the conductive blocks 141 may not overlap with the substrate 12, but not limited thereto. In some embodiments, the electronic device 8 may alternatively include the first seed layer SL1 and the second seed layer SL2 of any one of the embodiments of FIG. 4 to FIG. 7 or the first seed layer SL1, the second seed layer SL2, and the third seed layer SL3 of any one of the embodiments of FIG. 8 to FIG. 9.

As shown in FIG. 11, the substrate 12 may further have the recess R1, and the electronic device 8 may further include an electronic element 126 disposed in the recess R1. In the embodiment of FIG. 11, the active surface of the electronic element 126 may face the redistribution structure 104 and be electrically connected to the redistribution structure 104 through bonding pads 128. Disposing the electronic element 126 in the recess R1 may help shorten signal transmission path between the electronic element 126 and the electronic unit 106 and/or the electronic unit 116. The electronic element 126 may be attached to the recess R1, for example, by an adhesive layer 130, but not limited thereto. The electronic element 126 may, for example, include a resistor, a capacitor, an inductor, other suitable elements, or a combination thereof. In some embodiments, the substrate 12, the buffer layer 16 and the conductor layer 14 may also adopt any one of the electronic device 1 of FIG. 4 to the electronic device 6 of FIG. 9 described above.

As shown in FIG. 11, the electronic device 8 may further include a protection layer 132 disposed on the redistribution structure 104 and the first surface S1 of the substrate 12 to protect the redistribution structure 104. The protection layer 132 may have openings to expose the pads of the redistribution structure 104, so that the pads 106a of the electronic unit 106 and the pads 116a of the electronic unit 116 may be bonded to the pads of the redistribution structure 104 through the corresponding bonding pads 118. In some embodiments, the electronic device 8 may further include another protection layer 134 disposed on the redistribution structure 124 and the second surface S2 of the substrate 12 to protect the redistribution structure 124. The protection layer 134 may have openings to expose the pads of the redistribution structure 124, so that the bonding pads 110 may be bonded to the corresponding pads of the redistribution structure 124. The protection layer 132 and the protection layer 134 may include solder resist material or other suitable materials. According to some embodiments, the method of forming the electronic device 8 further includes a singulation step; that is, a plurality of electronic devices 8 may be formed at the same time, and a single, independent and qualified device may be formed by the singulation step. The singulation step includes wheel cutting or laser cutting. For example, laser light may be used to cut from one side of the protection layer toward the substrate to form electronic devices separated from each other. According to some embodiments, after a stack of all elements is formed or the redistribution structures are formed on both sides of the substrate with the through holes, the laser light may be used to simultaneously cut the redistribution structures on both sides of the substrate and the substrate with the through holes to form the electronic devices separated from each other. The singulation step described above may be applied to the manufacturing method of all electronic devices of the present disclosure. According to some embodiments, the wavelength of the laser light used for cutting may be different from the wavelength of the laser light used for modification. For example, the wavelength of the laser light used for cutting is greater than the wavelength of the laser light used for modification.

In one embodiment, the electronic unit 106 may be, for example, a control chip, and the electronic unit 116 may be, for example, a photonic integrated circuit. The electronic unit 116 may, for example, include an assembly structure of a photoelectric conversion element, an optical waveguide, a signal processing element, a micro-electromechanical element, and/or other suitable elements. In this case, the electronic device 8 may selectively further include an optical fiber 136 assembled on the electronic unit 116, so that the electronic unit 116 may receive an optical signal through the optical fiber 136. Other parts and other steps of the manufacturing method of the electronic device 8 of this embodiment may be identical or similar to the embodiment of FIG. 10, so the above content is referred to for them, and they will not be detailed redundantly.

Refer to FIG. 12, which schematically illustrates a cross-sectional view of an electronic device according to a ninth embodiment of the present disclosure. As shown in FIG. 12, the electronic device 9 of this embodiment differs from the electronic device 7 of FIG. 10 in that the substrate 12 may include a stack of multiple substrates. In the embodiment of FIG. 12, the substrate 12 includes a substrate 12a and a substrate 12b as an example, but not limited thereto. The substrate 12a and the substrate 12b may have a plurality of through holes THa and a plurality of through holes THb, respectively. The electronic device 9 may further include a seed layer SLa, a seed layer SLb, a conductor layer 14a, and a conductor layer 14b, wherein the conductor layer 14a may be disposed in the through holes THa and extend to a surface of the substrate 12a away from the substrate 12b, and the conductor layer 14b may be disposed in the through holes THb and extend to a surface of the substrate 12b away from the substrate 12a. The seed layer SLa is disposed between the conductor layer 14a and the substrate 12a, and the seed layer SLb is disposed between the conductor layer 14b and the substrate 12b. In some embodiments, the conductor layer 14a may not extend onto the surface of the substrate 12a away from the substrate 12b, and/or the conductor layer 14b may not extend onto the surface of the substrate 12b away from the substrate 12a. In some embodiments, a combination of the substrate 12a, the seed layer SLa and the conductor layer 14a and a combination of the substrate 12b, the seed layer SLb and the conductor layer 14b may alternatively adopt any one of the electronic device 1 of FIG. 4 to the electronic device 6 of FIG. 9 described above.

Similar to FIG. 10, in this embodiment, the conductor layer 14a and the conductor layer 14b may each include a plurality of conductive blocks, and the conductive blocks of the conductor layer 14a and the corresponding conductive blocks of the conductor layer 14b may respectively form a plurality of conductive vias CV penetrating through the substrate 12a and the substrate 12b. In this embodiment, the seed layer SLa and the seed layer SLb are different from each other, and the conductor layer 14a and the conductor layer 14b are different from each other, but not limited thereto. In some embodiments, the seed layer SLa and the seed layer SLb may be the same seed layer, and the conductor layer 14a and the conductor layer 14b may be the same conductor layer. The seed layer SLa and the seed layer SLb of this embodiment may each adopt the seed layer SL of FIG. 10 or the seed layer SL of FIG. 11, and the conductor layer 14a and the conductor layer 14b may each adopt the conductor layer 14 of FIG. 10 or the conductor layer 14 of FIG. 11, so that they are referred to the above content and will not be detailed redundantly. In some embodiments, the electronic device 8 may selectively further include the buffer layer 16 of any one of FIG. 4 to FIG. 9, but not limited thereto.

As shown in FIG. 12, the electronic device 9 may further include a circuit carrier 140, and the substrate 12 may be bonded to the circuit carrier 140 through the bonding pads 110. In the embodiment of FIG. 12, the circuit carrier 140 may include a substrate 144 and a plurality of conductive vias 146, wherein the substrate 144 may have a plurality of through holes TH1, and the conductive vias 146 may be respectively disposed in the corresponding through holes TH1 and penetrate through the substrate 144. The substrate 144 may include a plurality of substrates, for example, include a substrate 12c and a substrate 12d. The substrate 12c and the substrate 12d may be bonded to each other, and each of which may have a plurality of through holes, wherein one of the through holes of the substrate 12c and the corresponding through hole of the substrate 12d may form a through hole TH1. The conductive via 146 may, for example, include a block of the seed layer SL and a conductive block of the conductor layer 14. The seed layer SL and the conductor layer 14 of the conductive via 146 may, for example, be identical or similar to the seed layer SL and the conductor layer 14 of FIG. 10, respectively, and therefore, will not be described redundantly. In some embodiments, the substrate 144, the seed layer SL, and the conductive layer 14 may alternatively adopt any one of the electronic devices 1 of FIG. 4 to the electronic device 6 of FIG. 9.

It should be noted that the thickness of the substrate 12d may be greater than the thickness of the substrate 12c, so that the substrate 12d may carry the elements thereon. In addition, the thickness of the substrate 144 may be greater than the thickness of the substrate 12, so that the substrate 144 may support the elements thereon. The materials of the substrate 12a, the substrate 12b, the substrate 12c, and the substrate 12d of this embodiment may be identical or similar to the substrate 12 of FIG. 1 to FIG. 4, so they may be referred to the above content and will not be detailed redundantly.

As shown in FIG. 12, the circuit carrier 140 may further include a redistribution structure 148 and a redistribution structure 150 respectively disposed on an upper side and a lower side of the substrate 144. The redistribution structure 148 may be electrically connected to one end of each conductive via 146 to electrically connect the substrate 12 to the conductive via 146, and the redistribution structure 150 may electrically connect the other end of each conductive via 146 to the corresponding bonding pad 142 to be further electrically connected to other elements. The other elements include, but are not limited to, circuit boards or other electronic elements.

In the embodiment of FIG. 12, the substrate 12c of the substrate 144 may further have a recess R2, and the electronic device 9 may further include an electronic element 126 disposed in the recess R2. The active surface of the electronic element 126 may face the redistribution structure 148, and be electrically connected to the redistribution structure 148 through the bonding pads 128. Disposing the electronic element 126 in the recess R2 may help shorten the signal transmission path between the electronic element 126 and the electronic unit 106 and/or between the electronic element 126 and the electronic unit 116. The electronic element 126 may be attached to the recess R2, for example, by the adhesive layer 130, but not limited thereto. The electronic element 126 may be electrically connected to the redistribution structure 148 through the bonding pads 128. According to some embodiments, the electronic element 126 may selectively overlap with at least one of the electronic unit 106 or the electronic unit 116. According to some embodiments, the electronic element 126 may not overlap with the electronic unit 106 or the electronic unit 116.

In some embodiments, the electronic device 9 may further include a protection layer 152 disposed on the protection layer 122, the adhesive layer 112 and the circuit carrier 140 to protect the electronic unit 106, the electronic unit 116, the substrate 12, and the circuit carrier 140. The protection layer 152 may include, for example, a packaging material, but not limited thereto. According to some embodiments, the circuit carrier 140 may not include the redistribution structure. In some embodiments, the substrate 144 of FIG. 12 may alternatively include BT resin or other suitable substrate materials.

As shown in FIG. 12, in the manufacturing method of the electronic device 9, after the conductor layer 14a is formed in the through hole THa and on an upper surface of the substrate 12a, the redistribution structure 104 may be formed on the upper surface of the substrate 12a, and then the electronic unit 106 and the electronic unit 116 may be bonded to the redistribution structure 104. Next, the protection layer 122 is formed on the electronic unit 106, the electronic unit 116, the redistribution structure 104, and the substrate 12a. Since the step of forming the redistribution structure 104, the step of bonding the electronic unit 106 and the electronic unit 116, and the step of forming the protection layer 122 may be identical or similar to the embodiment of FIG. 10, they may be referred to the above content and will not be described redundantly.

In addition, the conductive layer 14b may be formed in the through hole THb and on a lower surface of the substrate 12b before, after or during any of the above steps. Then, an upper surface of the substrate 12b is bonded to a lower surface of the substrate 12a to form the substrate 12. Next, the substrate 12 may be bonded to the circuit carrier 140 through the bonding pads 110, and the protection layer 152 is formed on the protection layer 122, the adhesive layer 112 and the circuit carrier 140, thereby forming the electronic device 9.

In the embodiment of FIG. 12, the method of forming the substrate 144 may include, for example, bonding the substrate 12c having the through holes to the substrate 12d having the through holes, and then sequentially forming the seed layer SL and the conductor layer 14 in the through hole TH1, but not limited thereto. In some embodiments, the method of forming the substrate 144 may alternatively be identical to the method of forming the substrate 12. Other parts and other steps of the manufacturing method of the electronic device 8 of this embodiment may be the same or similar to the embodiment of FIG. 10, so the above content may be referred to for them, and they will not be detailed redundantly.

In summary, in the electronic device and the manufacturing method thereof of the present disclosure, since the first seed layer has an uneven surface, the adhesion between the second seed layer and the first seed layer may be improved. In addition, through the oxidation reaction of the first seed layer or through the catalytic reaction of the first seed layer, the second metal ions in the solution may produce the reduction reaction, thereby forming the second seed layer. Also, since the second seed layer is formed before forming the conductor layer, it helps to form the conductor layer on the first seed layer and the second seed layer, so that the conductor layer with a certain adhesion may be formed in the through hole with high aspect ratio.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate having a first surface and a second surface opposite to the first surface, wherein the substrate comprises a through hole, and the through hole has a sidewall connected to the first surface and the second surface;
a first seed layer disposed on the first surface, the second surface and the sidewall; and
a conductor layer disposed on the first seed layer,
wherein a roughness of a surface of the first seed layer is greater than or equal to 1 nm and less than or equal to 1 μm.

2. The electronic device as claimed in claim 1, further comprising a second seed layer disposed between the first seed layer and the conductor layer, wherein a crystallinity of the second seed layer is different from a crystallinity of the conductor layer.

3. The electronic device as claimed in claim 2, wherein an oxygen content of the second seed layer is different from an oxygen content of the conductor layer.

4. The electronic device as claimed in claim 2, wherein the second seed layer comprises a plurality of metal islands, and a particle size of one of the plurality of metal islands is less than 5 μm.

5. The electronic device as claimed in claim 4, wherein a density of the plurality of metal islands is greater than 0.12 per square micrometer.

6. The electronic device as claimed in claim 4, further comprising a third seed layer disposed among the plurality of metal islands and connected to the plurality of metal islands.

7. The electronic device as claimed in claim 2, wherein the first seed layer comprises a first metal, the second seed layer comprises a second metal, and an oxidation potential of the first metal is greater than a reduction potential of the second metal.

8. The electronic device as claimed in claim 2, further comprising an interface oxide layer disposed between the first seed layer and the conductor layer, wherein the interface oxide layer is disposed on a surface of the first seed layer without contacting the second seed layer.

9. The electronic device as claimed in claim 1, wherein the first seed layer comprises a polymer material and a third metal, the third metal is mixed with the polymer material, and the third metal comprises a noble metal.

10. The electronic device as claimed in claim 9, further comprising a buffer layer disposed between the substrate and the first seed layer, wherein the polymer material and the buffer layer comprise a same material.

11. An manufacturing method of an electronic device, comprising:
providing a substrate, wherein the substrate comprises a first surface and a second surface opposite to the first surface;
forming at least one through hole penetrating through the substrate, wherein the at least one through hole has a sidewall connected to the first surface and the second surface;
forming a first seed layer on the first surface, the second surface and the sidewall;
performing an electrochemical reaction to form a second seed layer on the first seed layer; and
forming a conductor layer on the first seed layer and the second seed layer after the electrochemical reaction,
wherein after the electrochemical reaction, a roughness of a surface of the first seed layer is greater than or equal to 1 nm and less than or equal to 1 μm.

12. The manufacturing method of the electronic device as claimed in claim 11, wherein the second seed layer comprises a plurality of metal islands, and a particle size of one of the plurality of metal islands is less than 5 μm.

13. The manufacturing method of the electronic device as claimed in claim 11, further comprising forming an interface oxide layer on a surface of the first seed layer without contacting the plurality of metal islands.

14. The manufacturing method of the electronic device as claimed in claim 11, wherein the first seed layer comprises a first metal, the second seed layer comprises a second metal, and the electrochemical reaction comprises oxidizing the first metal and reducing the second metal.

15. The manufacturing method of the electronic device as claimed in claim 14, wherein an oxidation potential of the first metal is greater than a reduction potential of the second metal.

16. The manufacturing method of the electronic device as claimed in claim 11, wherein the electrochemical reaction comprises immersing the first seed layer into a solution, a pH value of the solution ranges from 1 to 5, the solution comprises a plurality of fluorine ions and a plurality of metal ions, a molar concentration of the plurality of fluorine ions ranges from 0.1 M to 1 M, and a molar concentration of the plurality of metal ions ranges from 0.5 M to 5.5 M.

17. The manufacturing method of the electronic device as claimed in claim 11, wherein the electrochemical reaction comprises etching a surface of the first seed layer away from the substrate to form an uneven surface.

18. The manufacturing method of the electronic device as claimed in claim 11, wherein the first seed layer comprises a polymer material and a third metal, the second seed layer comprises a second metal, and the electrochemical reaction comprises using the third metal as a catalytic to reduce the second metal.

19. The manufacturing method of the electronic device as claimed in claim 11, further comprising forming a buffer layer on the first surface, the second surface and the sidewall between providing the substrate and forming the first seed layer.

20. The manufacturing method of the electronic device as claimed in claim 19, wherein a thickness of the buffer layer is less than or equal to 10 μm.
